(19) United States
(12) Patent Application Publication
(10) Pub. No.: US 2026/0337772 A1
(43) Pub. Date: Oct. 29, 2026

(54) COMPOSITION FOR DEPOSITING THIN FILM CONTAINING METAL COMPOUND, METHOD FOR MANUFACTURING METAL-CONTAINING THIN FILM USING SAME, AND METAL-CONTAINING THIN FILM MANUFACTURED BY USING SAME

(71) Applicant: DNF CO., LTD., Daejeon (KR)

(72) Inventors: Yonghee KWONE, Daejeon (KR); Taeseok BYUN, Daejeon (KR); Sangyong JEON, Daejeon (KR); Sangchan LEE, Daejeon (KR); Youngjae IM, Daejeon (KR); Sangick LEE, Daejeon (KR)

(21) Appl. No.: 19/107,709

(22) PCT Filed: Aug. 29, 2023
(86) PCT No.: PCT/KR2023/012751

§ 371 Date: Feb. 28, 2025

(30) Foreign Application Priority Data
Sep. 2, 2022 (KR) 10-2022-0111582

(51) Int. Cl. C23C 16/455; C01G 15/00; C07F 5/00; C23C 16/40; C23C 16/46

(52) U.S. Cl. CPC C23C 16/45553; C01G 15/00; C07F 5/00; C23C 16/407; C23C 16/45536; C23C 16/46

(57) ABSTRACT

Depositing a metal-containing thin film including a metal compound, a method for producing a metal-containing thin film, and a metal-containing thin film produced using the method are described. A high-quality metal-containing thin film having uniform components may be produced at an improved deposition speed.

### TECHNICAL FIELD

The present invention relates to a composition for depositing a thin film including a metal compound, a method for producing a metal compound, a method for producing a metal-containing thin film using the same, and a metal-containing thin film produced therefrom.

### BACKGROUND ART

In recent years, demand for a thin-film display electronic device such as an organic light-emitting diode has rapidly increased, and thus, a thin film material showing excellent performance of low power, high resolution, and high reliability is required.

Conventionally, silicon is most used as a thin film material used in a display electronic device, but a metal oxide which has higher charge mobility and is more easily processed at a low temperature than polycrystalline silicon is currently used. Since a metal oxide has a large energy band gap and excellent light transmittance, it is expected to be a material which may improve uniformity and mobility which are conventional disadvantages of silicon.

In particular, a Group 13 metal oxide may be used as a transparent oxide semiconductor material and be applied as an electrode, a conductive coating material, and the like. Indium and gallium among the Group 13 metals are useful due to their characteristics of excellent resistance to wear and low resistance when they are in contact with an aluminum wire.

When the metal thin film described above is formed by sputtering using a sputter target, since the composition of a deposited thin film is determined by the sputter target, there is a limitation in uniformly adjusting the composition of the thin film and it is difficult to maintain a uniform thin film composition and a uniform thickness during deposition of a large area.

Therefore, in order to overcome the problems, the metal thin film is produced by a method such as atomic layer deposition (ALD), chemical vapor deposition (CVD), and pulsed laser deposition (PLD), instead of sputtering. Indium chloride (III) which is a conventionally used metal precursor may cause chlorine contamination during thin film deposition using a method such as atomic layer deposition, chemical vapor deposition, and pulsed laser deposition, and needs an oxygen source from outside. In addition, a trialkyl indium (III) precursor such as trimethyl indium and triethyl indium, which is conventionally widely used, is sensitive to oxygen and moisture and is solid, and thus, may cause a problem in terms of vapor pressure adjustment and reproducibility of a uniform film.

Therefore, development of a high-quality metal precursor which does not contain a halogen, has excellent thermal stability to high temperature, and has high volatility is needed, as a material which may solve the above problems.

### RELATED ART DOCUMENTS

### Patent Documents

(Patent Document 1) Korean Patent Registration No. 10-2029071 B1

### DISCLOSURE

### Technical Problem

An object of the present invention is to provide a composition for depositing a thin film including a metal compound showing excellent volatility and thermal stability.

Another object of the present invention is to provide a method for producing a metal compound.

Still another object of the present invention is to provide a method for producing a thin film which may show improved deposition speed and reproducibility, using the composition for depositing a thin film.

The present invention provides a high-quality metal-containing thin film which has uniform components and shows a uniform thickness by adopting the composition for depositing a thin film.

### Technical Solution

In one general aspect, a composition for depositing a thin film includes: a metal compound represented by the following Chemical Formula 1:

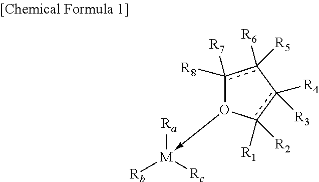

wherein
M is In or Ga;
[symbol] is a single bond or a double bond;
Rₐ to R_{c} are independently of one another C1-C7 alkyl;
R₁ to R₈ are independently of one another hydrogen or C1-C7 alkyl; and
when [symbol] is a double bond, R₁, R₃, R₅, and R₇ do not exist.

In Chemical Formula 1, M may be In or Ga, [symbol] is a single bond or a double bond, Rₐ to R_{c} may be independently of one another C1-C4 alkyl, and R₁ to R₈ may be independently of one another hydrogen or C1-C4 alkyl.

The metal compound according to an exemplary embodiment of the present invention may be represented by the following Chemical Formula 2:

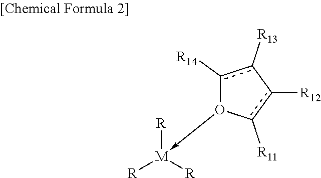

wherein
M is In or Ga;
[symbol] is a single bond or a double bond;
R is C1-C7 alkyl; and
R₁₁ to R₁₄ are independently of one another hydrogen or C1-C7 alkyl.

In Chemical Formula 2, M may be In or Ga; [symbol] may be a single bond or a double bond; R may be C1-C4 alkyl; and R₁₁ to R₁₄ may be independently of one another hydrogen or C1-C4 alkyl.

The metal compound according to an exemplary embodiment may be represented by the following Chemical Formula 3:

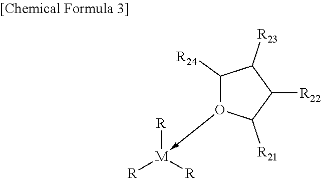

wherein
M is In or Ga;
R is C1-C3 alkyl; and
R₂₁ to R₂₄ are independently of one another hydrogen or C1-C4 alkyl.

In another general aspect, a method for producing a metal compound represented by the following Chemical Formula 1 includes: reacting compounds represented by the following Chemical Formulae 11 to 15 to produce the compound represented by Chemical Formula 1:

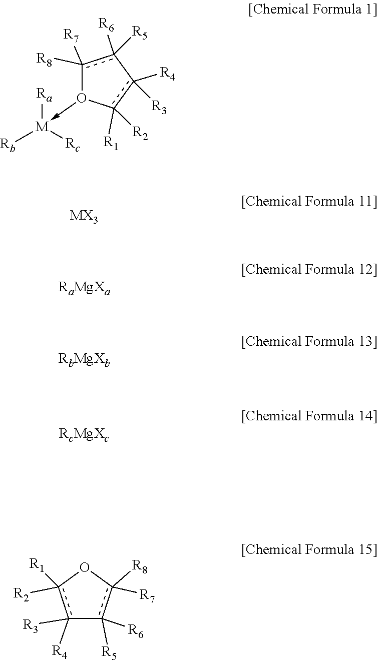

wherein
M is In or Ga;
[symbol] is a single bond or a double bond;
Rₐ to R_{c} are independently of one another C1-C7 alkyl;
R₁ to R₈ are independently of one another hydrogen or C1-C7 alkyl;
X, Xₐ, X_{b}, and X_{c} are independently of one another a halogen; and
when [symbol] is a double bond, R₁, R₃, R₅, and R₇ do not exist.

The method for producing a metal compound according to an exemplary embodiment of the present invention may further include adding a polar solvent and performing stirring, after the producing of the compound of Chemical Formula 1.

An amount of the added polar solvent may be 2 to 5 equivalents with respect to the compound represented by Chemical Formula 1.

In another general aspect, a method for producing a metal-containing thin film using the metal compound according to an exemplary embodiment or a composition for depositing a thin film including the metal compound is provided.

The method for producing a metal-containing thin film may include: a) heating a substrate mounted in a chamber; b) injecting the metal compound or the composition for depositing a thin film including the metal compound into the chamber and adsorbing it to the substrate; and c) injecting a reaction gas into the substrate to which the metal compound or the composition for depositing a thin film including the metal compound is adsorbed to produce a metal-containing thin film, wherein a temperature of the substrate may be 100 to 450° C.

In still another general aspect, a metal-containing thin film produced using the metal compound according to an exemplary embodiment of the present invention or a composition for depositing a thin film including the metal compound is provided.

The metal-containing thin film may have a metal content of 20 to 60 wt %.

### Advantageous Effects

The composition for depositing a thin film including the metal compound of the present invention includes a metal compound having a specific structure, thereby showing high volatility and having excellent thermal stability and storage stability.

The method for producing a metal compound according to an exemplary embodiment of the present invention may obtain a high yield by a simple process, and produce a compound of Chemical Formula 1 with a high purity.

The method for producing a metal-containing thin film of the present invention may show an improved deposition speed by adopting the composition for depositing a thin film of the present invention, and may provide a uniform step coverage for a three-dimensional device. In addition, the metal-containing thin film produced using the composition for depositing a thin film of the present invention may have uniform components and a uniform thickness, and show electrically excellent performance.

### DESCRIPTION OF DRAWINGS

The above and other objects, features and advantages of the present invention will become apparent from the following description of preferred embodiments given in conjunction with the accompanying drawings, in which:

FIG. 1 is a drawing showing TGA analysis results of Example 2 of the present invention and [(3-dimethylamino)propyl]dimethylindium (DADI).

FIG. 2 is a drawing showing vapor pressure measurement results of Example 2 of the present invention and [(3-dimethylamino)propyl]dimethylindium (DADI).

FIG. 3 is a drawing showing results of measuring thermal stability of Example 2 of the present invention and [(3-dimethylamino)propyl]dimethylindium (DADI).

FIG. 4 is a drawing showing a deposition speed depending on time of injecting precursors of Example 3 and Comparative Example 1.

FIG. 5 is a drawing showing a deposition speed depending on vapor pressure of the precursors of Example 3 and Comparative Example 1.

FIG. 6 is a drawing showing a deposition speed depending on temperature of silicon substrates of Example 3 and Comparative Example 1.

FIG. 7 is a drawing showing a deposition thickness depending on process cycles of Example 3 and Comparative Example 1.

FIG. 8 is a drawing showing XRD patterns of Example 3 and Comparative Example 1.

### BEST MODE

Hereinafter, a composition for depositing a thin film including a metal compound of the present invention, a method for producing a metal-containing thin film using the composition, and a metal-containing thin film produced by adopting the method will be described in detail.

The singular form used in the present invention may be intended to also include a plural form, unless otherwise indicated in the context.

In addition, the numerical range used in the present invention includes all values within the range including the lower limit and the upper limit, increments logically derived in a form and span in a defined range, all double limited values, and all possible combinations of the upper limit and the lower limit in the numerical range defined in different forms. Unless otherwise defined in the specification of the present invention, values which may be outside a numerical range due to experimental error or rounding off of a value are also included in the defined numerical range.

The term “comprise” described in the present invention is an open-ended description having a meaning equivalent to the term such as “is/are provided”, “contain”, “have”, or “is/are characterized”, and does not exclude elements, materials, or processes which are not further listed.

The number of carbons described in the present invention does not include the number of carbons of substituents, and as an example, C1-C7 alkyl refers to alkyl having 1 to 7 carbon atoms which does not include the number of carbons of the substituents of the alkyl.

Hereinafter, the present invention will be described in detail. Here, technical terms and scientific terms used in the present specification have the general meaning understood by a person skilled in the art unless otherwise defined, and a description for the known function and configuration obscuring the present invention will be omitted in the following description.

The present invention provides a composition for depositing a thin film including a metal compound represented by the following Chemical Formula 1:

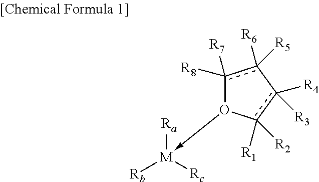

wherein
M is In or Ga;
[symbol] is a single bond or a double bond;
Rₐ to R_{c} are independently of one another C1-C7 alkyl;
R₁ to R₈ are independently of one another hydrogen or C1-C7 alkyl; and
when [symbol] is a double bond, R₁, R₃, R₅, and R₇ do not exist.

Since the metal compound represented by Chemical Formula 1 may have a chiral center, the compound may be used in an optically pure form or provided as a diastereomeric mixture or a racemic mixture. The term “racemic mixture” refers to a mixture of two enantiomers at the same ratio.

The metal compound may have a single evaporation step at 50° C. or higher, and its residue mass at 500° C. may be 0.001 to 1 wt %, specifically 0.01 to 0.9 wt %, and more specifically 0.1 to 0.7 wt %. The metal compound has higher volatility and improved vapor pressure and may have a high deposition speed, and has excellent stability and is easy to handle when it is stored as a compound having improved thermal stability.

In Chemical Formula 1, M may be In or Ga, [symbol] is a single bond or a double bond, Rₐ to R_{c} may be independently of one another C1-C4 alkyl, and R₁ to R₈ may be independently of one another hydrogen or C1-C4 alkyl.

Specifically, in the metal compound represented by Chemical Formula 1, M may be In or Ga, [symbol] may be a single bond or a double bond, Rₐ to R_{c} may be independently of one another C1-C3 alkyl, and R₁ to R₈ may be independently of one another hydrogen or C1-C3 alkyl.

The metal compound according to an exemplary embodiment of the present invention may be represented by the following Chemical Formula 2:

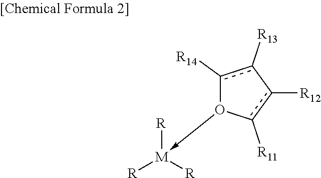

wherein
M is In or Ga;
[symbol] is a single bond or a double bond;
R is C1-C7 alkyl; and
R₁₁ to R₁₄ are independently of one another hydrogen or C1-C7 alkyl.

In Chemical Formula 2, when [symbol] is a single bond, each carbon of a

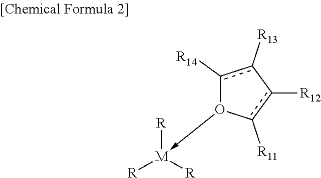

ring has R₁₁ to R₁₄ and separate hydrogen which is not shown exists, respectively, and when [symbol] is a double bond, only R₁₁ to R₁₄ exist.

In Chemical Formula 2, M may be In or Ga; [symbol] may be a single bond or a double bond; R may be C1-C4 alkyl; and R₁₁ to R₁₄ may be independently of one another hydrogen or C1-C4 alkyl.

The metal compound according to an exemplary embodiment may be represented by the following Chemical Formula 3:

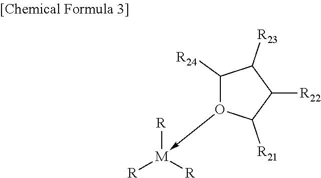

wherein
M is In or Ga;
R is C1-C3 alkyl; and
R₂₁ to R₂₄ are independently of one another hydrogen or C1-C4 alkyl.

In addition, the present invention provides a method for producing a metal compound represented by the following Chemical formula 1 according to an exemplary embodiment, and specifically, includes: reacting compounds represented by the following Chemical Formulae 11 to 15 to produce the metal compound represented by Chemical Formula 1:

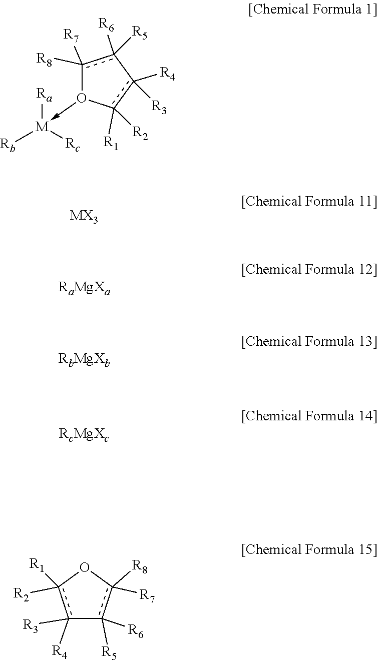

wherein
M is In or Ga;
[symbol] is a single bond or a double bond;
Rₐ to R_{c} are independently of one another C1-C7 alkyl;
R₁ to R₈ are independently of one another hydrogen or C1-C7 alkyl;
X, Xₐ, X_{b}, and X_{c} are independently of one another a halogen; and
when [symbol] is a double bond, R₁, R₃, R₅, and R₇ do not exist.

Specifically, the producing of the compound of Chemical Formula 1 may be performed by adding a solvent to the compound represented by Chemical Formula 11, adding the compounds represented by Chemical Formulae 12 to 15 at 0 to 30° C., and reacting the compounds at 5 to 50° C. for 1 to 15 hours, specifically 10 to 40° C. for 1 to 12 hours, and more specifically 15 to 35° C. for 1 to 10 hours.

As another embodiment, the compounds of Chemical Formulae 12 to 14 may be the same compounds, and may be a Grignard reagent included in the solvent of Chemical Formula 15.

The method for producing a metal compound according to an exemplary embodiment of the present invention may further include reacting the compounds of Chemical Formulae 11 to 15 to produce the compound of Chemical Formula 1, adding a polar solvent, and performing stirring.

The polar solvent according to an exemplary embodiment of the present invention may be one or two or more selected from acetonitrile, dimethylsulfoxide (DMSO), dimethylformamide (DMF), and tetrahydrofuran (THF), specifically dimethylformamide (DMF), tetrahydrofuran (THF), or a mixture thereof, and more specifically tetrahydrofuran (THF), but is not limited thereto.

In addition, an amount of the polar solvent according to an exemplary embodiment of the present invention may be 2 to 5 equivalents, specifically 2 to 4.5 equivalents, and more specifically 2 to 4 equivalents with respect to the compound represented by Chemical Formula 11.

In the process of producing a metal compound, a MgCl₂ precipitate may be produced, and it is regarded as a reaction by-product which has a small particle size so that it is not easily removed with a filter and has a long filtration time to greatly decrease purity and yield of a final compound.

Therefore, according to the method for producing a metal compound of the present invention, when adding of a polar solvent to produce a MgCl₂ precipitate, in particular, adding of a polar solvent in an excessive amount, is included, the metal compound represented by Chemical Formula 1 may be easily separated with high purity.

This is considered that since a complex compound of the polar solvent and MgCl₂ is formed, it is easy to separate the by-product and the metal compound and the purity and the yield of the metal compound is high.

Specifically, when the polar solvent such as THF is used, it is expected that a complex compound in the form of MgCl₂ (THF)ₙ (n=2, 3) is formed. It is considered that the compound formed of the complex compound as such has much improved filterability, and by filtering and removing these complex compounds easily, the purity and the yield of a final product may be significantly improved.

In the method for producing a metal compound according to an exemplary embodiment of the present invention, the polar solvent is added to a reaction product of Chemical Formulae 11 to 15 and stirring may be performed for 0.5 to 5 hours.
In addition, in the reacting of the compounds of Chemical Formulae 11 to 15 to produce the compound of Chemical Formula 1, any solvent may be used as long as it is a common organic solvent, but the solvent may be one or two or more selected from hexane, pentane, dichloromethane (DCM), benzene, and toluene, and is not limited thereto.

Each reaction of the production method may be completed after confirming that a starting material is completely consumed by NMR, and after reaction completion, an extraction process, a process of distilling the solvent under reduced pressure, and a process of separating and purifying the compound by a common method such as tube chromatography may be further performed.

The method for producing a metal compound may produce a high-purity metal compound with a high yield, and allow production by a mild and simple process, and thus, its industrial use may be easy.

Since the metal compound has a uniform vapor pressure during the deposition process, the composition of the thin film is maintained constant, thereby producing a uniform thin film having uniform components. In addition, since the film has a uniform thickness and may show excellent step coverage, a thin film which shows excellent physical properties even in a three-dimensional device may be produced.

The present invention provides a method for producing a metal compound-containing thin film using the metal compound according to an exemplary embodiment or a composition for depositing a thin film including the metal compound.

The method for producing a metal-containing thin film according to an exemplary embodiment of the present invention may produce a thin film having a multi-layer structure including a dissimilar metal, which may have a structure in which the metal compound or a composition for depositing a metal-containing thin film and a precursor of a dissimilar metal are sequentially deposited and laminated, or may be formed by mixing the metal compound or the composition for depositing a metal-containing thin film and a precursor of a dissimilar metal and depositing the mixture.

The method for producing a metal-containing thin film may include: a) heating a substrate mounted in a chamber; b) injecting the metal compound according to an exemplary embodiment of the present invention or the composition for depositing a thin film into the chamber and adsorbing it to the substrate; and c) injecting a reaction gas into the substrate to which the metal compound or the composition for depositing a thin film is adsorbed to produce a metal-containing thin film.

The reaction gas may be any one or two or more selected from oxygen (O₂), ozone (O₃), water vapor (H₂O), hydrogen peroxide (H₂O₂), nitrogen monoxide (NO), nitrous oxide (N₂O), nitrogen dioxide (NO₂), ammonia (NH₃), nitrogen (N₂), hydrazine (N₂H₄), amine, diamine, hydrogen (H₂), argon (Ar), and helium (He), and the transfer gas is inert gas and may be any one or two or more selected from argon (Ar), helium (He), and nitrogen (N₂), and specifically nitrogen (N₂), but is not limited thereto.

In addition, in the method for producing a metal-containing thin film according to an exemplary embodiment of the present invention, when steps b) and c) are set as one cycle, the cycles may be repeated until a metal-containing thin film having a desired thickness is produced, and specifically, may be 50 to 5,000 cycles and more specifically 200 to 2,000 cycles, but are not limited thereto.

A temperature of the substrate of step a) may be 100 to 450° C., specifically 150 to 300° C., and more specifically 150 to 250° C. Since the composition for depositing a thin film according to an exemplary embodiment of the present invention may be deposited without thermal decomposition of the metal compound at a high temperature as the above temperature, stability and productivity may be improved in operating a deposition process.

In addition, since the metal-containing thin film produced by the method for producing a metal-containing thin film has a surprisingly decreased content of impurities such as carbon, a high-quality metal-containing thin film may be produced.

The substrate used in the method for producing a metal-containing thin film according to an exemplary embodiment may include one or two or more substrates selected from the group consisting of glass, silicon, metal polyester (PE), polyethylene terephthalate (PET), polyethylene naphthalate (PEN), polycarbonate (PC), polyetherimide (PEI), polyethersulfone (PES), polyetheretherketone (PEEK), and polyimide (PI), but is not limited thereto.

In step b) of the method for producing a metal-containing thin film according to an exemplary embodiment, the composition for depositing metal-containing thin film is filled into a steel bubbler container and the temperature may be maintained at 20 to 100° C., specifically 30 to 90° C., and more specifically 40 to 70° C.

In addition, the conditions of a deposition process of step b) may be adjusted depending on the structure and the thermal properties of the thin film. A flow rate of the metal compound added according to an exemplary embodiment may be 1 to 1000 sccm as a bubbler type, a flow rate of the transfer gas added may be 1 to 5000 sccm, a flow rate of the reaction gas added may be 10 to 5000 sccm, the pressure may be adjusted to a range of 0.1 to 10 torr, and an injection time may be 0.1 to 20 seconds, preferably 0.1 to 15 seconds, and more preferably 0.1 to 10 seconds, but are not limited thereto. When the metal-containing thin film is produced within the range, uniformity of the thickness of the thin film is much improved, and thus, excellent step coverage may be maintained even in a substrate having a complicated shape.

The method for producing a metal-containing thin film according to an exemplary embodiment may further include purging with a transfer gas in order to remove an unabsorbed metal compound or a composition for depositing a thin film including the same or remove by-products produced after injecting the reaction gas and a remaining reaction gas.

The method for producing an indium-containing thin film according to an exemplary embodiment of the present invention may be performed by atomic layer deposition (ALD), chemical vapor deposition (CVD), metal organic chemical vapor deposition (MOCVD), low pressure chemical vapor deposition (LPCVD), plasma enhanced chemical vapor deposition (PECVD), plasma enhanced chemical vapor deposition (PEALD), or pulsed laser deposition (PLD), preferably by atomic layer deposition (ALD), chemical vapor deposition (CVD), or metal organic chemical vapor deposition (MOCVD).

The present invention provides a metal-containing thin film produced using the metal compound according to an exemplary embodiment of the present invention or the composition for depositing a thin film including the metal compound, and the metal-containing thin film may show electrically excellent performance having uniform components.

The metal-containing thin film may have a metal content of 20 to 60 wt %.

Hereinafter, the metal compound according to the present invention and the composition for depositing a thin film including the metal compound, the method for producing a metal-containing thin film using the same, and the metal-containing thin film produced therefrom will be described in more detail by the specific examples.

However, the following examples are only a reference for describing the present invention in detail, and the present invention is not limited thereto and may be implemented in various forms. In addition, the terms used herein are only for effectively describing certain examples, and are not intended to limit the present invention.

In addition, unless otherwise noted, all of the examples were performed using technologies of handling air-sensitive materials commonly known in the art, for example, “Schlenk techniques”, under an inert atmosphere, for example, purified nitrogen (N₂) or argon (Ar).

### [Example 1] Production of Indium Compound (InMe₃(THF))

To a 5 L three-neck flask including a stirrer and a condenser, 100 g (0.45 mol) of InCl₃ was added and dried under vacuum. 1000 ml of n-hexane was added thereto, 452 ml of MeMgCl (3.0 M solution in THF) was slowly added while the temperature was maintained at 10° C., and then stirring was performed at room temperature for 8 hours to produce a light gray product. Thereafter, the reactant was filtered, the solvent and volatile by-products of the filtrate was removed under vacuum, and distillation under reduced pressure (23° C., 0.8 torr) was performed to obtain 37.1 g of a metal compound which was a colorless liquid (yield: 35%).

¹H NMR (400 MHz, C6D6) δ 3.2 (m, 4H), 1.1 (m, 4H), −0.1 (s, 9H)

### [Example 2] Production of Indium Compound (InMe₃(THF))

To a 5 L three-neck flask including a stirrer and a condenser, 100 g (0.45 mol) of InCl³ was added and dried under vacuum. 1000 ml of n-hexane was added thereto, 452 ml of MeMgCl (3.0 M solution in THF) was slowly added while the temperature was maintained at 10° C., and then stirring was performed at room temperature for 8 hours. 3 equivalents of THF was further added at room temperature to the reactant after completing the reaction, stirring was performed for 2 hours, filtration was performed, the solvent and volatile by-products of the filtrate was removed under vacuum, and distillation under reduced pressure (23° C., 0.8 torr) was performed to obtain 77.3 g of a metal compound which was a colorless liquid (yield: 73%).

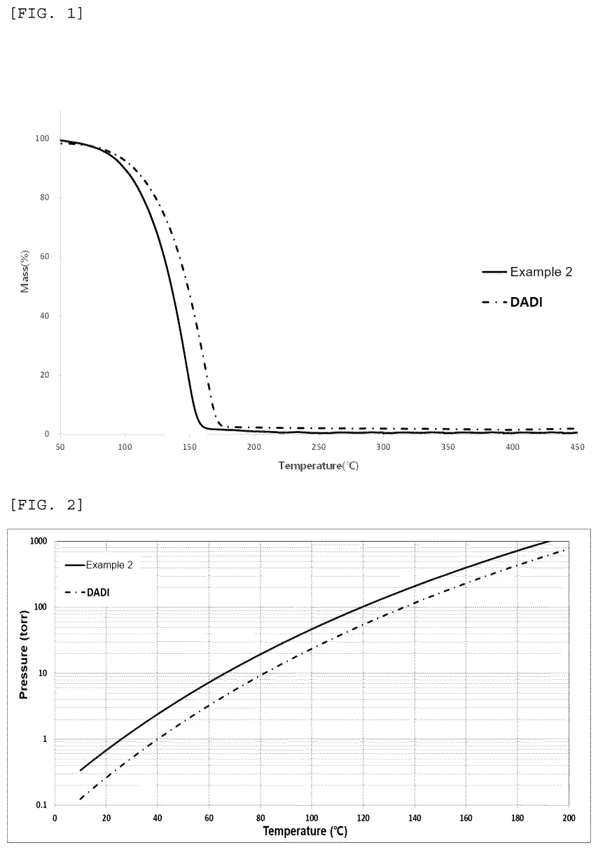

¹H NMR (400 MHz, C6D6) δ 3.2 (m, 4H), 1.1 (m, 4H), −0.1 (s, 9H) In FIG. 1, a TGA graph of the metal compound of Example 2, InMe₃(THF) is shown, and as a result of comparing it with the TGA graph of [(3-dimethylamino)propyl]dimethylindium (hereinafter, referred to as DADI, DOCK/CHEMICALS), which is commonly used in conventional indium-containing thin film deposition, it was found that the metal compound has a single evaporation step from about 50° C., a temperature in a ½ weight decrease part was shown to be lower by 12° C. than DADI, and a residue mass at 500° C. was confirmed to be 0.4%. It was found from the results that the metal compound of Example 2 of the present invention showed faster vaporization characteristics than DADI and 99% or more of the metal compound vaporized without thermal decomposition.

A vapor pressure was measured for confirming the improved vapor pressure characteristics of Example 2 (InMe₃(THF)), and is shown in FIG. 2, as compared with the vapor pressure of DADI.

As shown in FIG. 2, as a result of measuring the vapor pressure, it was confirmed that the vapor pressure (26° C. @ 1 torr) of Example 2 (InMe₃(THF)) was significantly improved as compared with the vapor pressure of DADI (41° C. @ 1 torr).

It was found from the results that when an indium-containing thin film was deposited by chemical vapor deposition (CVD) or atomic layer deposition (ALD) using Example 2 (InMe₃(THF)), it would be much more advantageous than a conventional indium precursor.

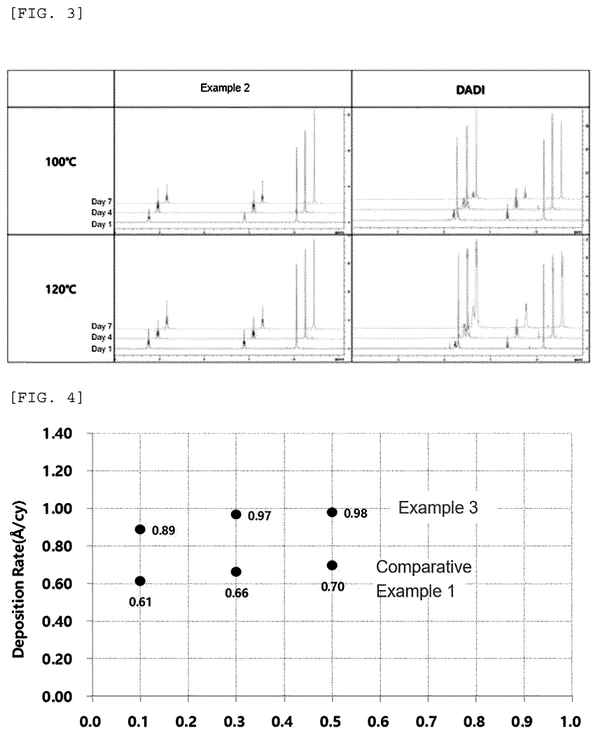

In a glove box under an argon atmosphere, a predetermined dose (3 g) of Example 2 (InMe₃(THF)) and DADI were added, respectively to a sealable stainless container and the container was sealed, the container was stored under the conditions of predetermined temperature (100° C., 120° C.) and time (1 day, 4 days, 7 days), and each sample was analyzed by 1H NMR to confirm peak change, thereby measuring thermal stability of Example 2 (InMe₃(THF)) and DADI, and the results are shown in FIG. 3.

As shown in FIG. 3, both Example 2 (InMe₃(THF)) and DADI were stable without any change at 100° C. until day 7. However, at 120° C., there was no change in Example 2 (InMe₃(THF)), but it was confirmed that by-products were produced from day 4 in DADI.

Thus, it was found that Example 2 (InMe₃(THF)) had significantly excellent stability under high temperature conditions, as compared with DADI which is widely used in indium-containing thin film deposition.

### [Example 3] Production of Indium Oxide Thin Film

InMe₃(THF) according to Example 2 was used and nitrous oxide (N₂O) was used as a reaction gas to produce an indium-containing oxide thin film by plasma enhanced atomic layer deposition (PEALD).

A silicon substrate was loaded inside a deposition chamber, and a temperature of the substrate was maintained at a certain temperature. InMe₃(THF) was filled into a stainless steel bubbler container, and the temperature corresponding to a certain vapor pressure was maintained.

An argon gas was used as a transfer gas, and a InMe₃(THF) precursor was injected into the deposition chamber for a certain period of time and adsorbed. Thereafter, the argon gas (600 sccm) was used to perform purging for 3 seconds to remove the InMe₃(THF) and reaction by-products remaining in the deposition chamber.

Plasma was used while nitrous oxide (N₂O) was injected as a reaction gas, thereby forming an indium-containing oxide thin film. Thereafter, the argon gas (600 sccm) was used to perform purging for 3 seconds to remove residual reaction gas and reaction by-products.

70 to 700 cycles were performed with the processes described above being one cycle to produce an indium-containing oxide thin film, and the thickness of the deposited indium oxide thin film was measured using an ellipsometer.

The conditions of depositing the indium oxide thin film are shown in the following Table 1.

### [Comparative Example 1] Production of Indium Oxide Thin Film

A metal-containing thin film was produced by a plasma enhanced atomic layer deposition (PEALD), using DADI which is currently widely used in production of an indium-containing thin film and nitrous oxide (N₂O) as a reaction gas.

The indium oxide thin film was formed in the same manner as in Example 3, except that DADI was used as the precursor, and the deposition conditions of the indium oxide thin film are shown in the following Table 1

TABLE 1

| | | | | Source feeding | | | | | |
|---|---|---|---|---|---|---|---|---|---|
| | | | | Time | | Reactant | | | |
| | | Vapor | Wafer | Bubble | | | RF | | |
| | Evaluation | pressure | temp. | Ar | Time | N₂O | power | Time | Cycle |
| | item | (Torr) | (°C) | (sccm) | (sec) | (sccm) | (W) | (sec) | (No.) |
| Example 3 | Source | 4 | 200 | 50 | 0.1 | 400 | 400 | 3 | 300 |
| | feeding | 4 | 200 | 50 | 0.3 | 400 | 400 | 3 | 300 |
| | time | 4 | 200 | 50 | 0.5 | 400 | 400 | 3 | 300 |
| | Vapor | 1 | 200 | 50 | 0.5 | 400 | 400 | 3 | 300 |
| | pressure | 4 | 200 | 50 | 0.5 | 400 | 400 | 3 | 300 |
| | | 5 | 200 | 50 | 0.5 | 400 | 400 | 3 | 300 |
| | | 12 | 200 | 50 | 0.5 | 400 | 400 | 3 | 300 |
| | Wafer | 4 | 140 | 50 | 0.5 | 400 | 400 | 3 | 300 |
| | temp. | 4 | 150 | 50 | 0.5 | 400 | 400 | 3 | 300 |
| | | 4 | 180 | 50 | 0.5 | 400 | 400 | 3 | 300 |
| | | 4 | 200 | 50 | 0.5 | 400 | 400 | 3 | 300 |
| | | 4 | 220 | 50 | 0.5 | 400 | 400 | 3 | 300 |
| | Linearity | 4 | 200 | 50 | 0.5 | 400 | 400 | 3 | 70~700 |
| Comparative | Source | 4 | 200 | 50 | 0.1 | 400 | 400 | 3 | 300 |
| Example 1 | feeding | 4 | 200 | 50 | 0.3 | 400 | 400 | 3 | 300 |
| | time | 4 | 200 | 50 | 0.5 | 400 | 400 | 3 | 300 |
| | Vapor | 1 | 200 | 50 | 0.5 | 400 | 400 | 3 | 300 |
| | pressure | 4 | 200 | 50 | 0.5 | 400 | 400 | 3 | 300 |
| | | 5 | 200 | 50 | 0.5 | 400 | 400 | 3 | 300 |
| | Wafer | 4 | 140 | 50 | 0.5 | 400 | 400 | 3 | 300 |
| | temp. | 4 | 150 | 50 | 0.5 | 400 | 400 | 3 | 300 |
| | | 4 | 180 | 50 | 0.5 | 400 | 400 | 3 | 300 |
| | | 4 | 200 | 50 | 0.5 | 400 | 400 | 3 | 300 |
| | | 4 | 220 | 50 | 0.5 | 400 | 400 | 3 | 300 |
| | Linearity | 4 | 200 | 50 | 0.5 | 400 | 400 | 3 | 70~700 |

In FIG. 4, the deposition speed per one cycle depending on the injection time of the precursors of Example 3 and Comparative Example 1 is shown. It was found that the deposition speeds of Example 3 and Comparative Example 1 tended to increase due to physical adsorption as the injection time increased, but were saturated at the injection time of 0.3 seconds or more and hardly increased. In particular, it was found that the deposition speed of Example 3 was significantly improved by 40% or more as compared with Comparative Example 1.

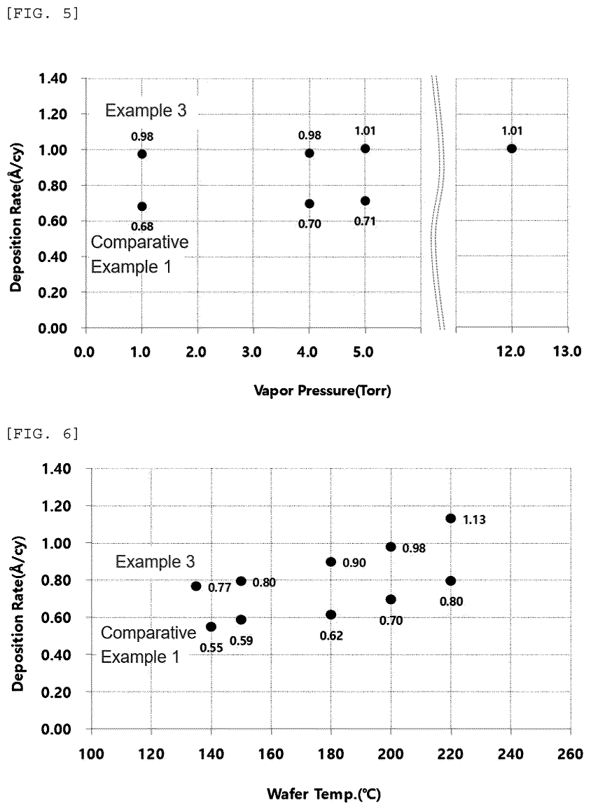

In FIG. 5, the deposition speed per one cycle depending on the vapor pressure of the precursors of Example 3 and Comparative Example 1 is shown. It was found that the vapor pressures of the precursors of Example 3 and Comparative Example 1 were stabilized at 1 torr or more, and, in particular, in Example 3, since a relatively constant deposition speed was shown even at a high vapor pressure of 12 torr, a self-limited reaction which is the characteristic of ALD was confirmed. In addition, it was found that Example 3 showed significantly improved results by 40% or more as compared with Comparative Example 1 even at a deposition speed depending on the vapor pressure similarly to the above results.

In FIG. 6, the deposition speed per one cycle depending on the temperature of the silicon substrates of Example 3 and Comparative Example 1 is shown. Like the above results, Example 3 showed the results improved by 40% or more as compared with Comparative Example 1 even at a deposition speed depending on the temperature of the silicon substrate, and thus, was confirmed to show a significantly improved deposition speed.

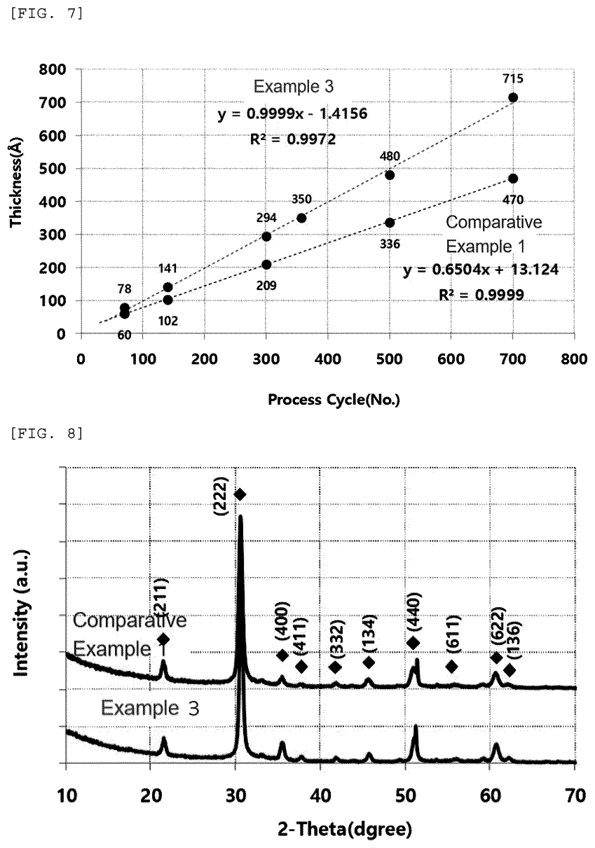

In FIG. 7, the thickness of the thin film depending on the process cycle in Example 3 and Comparative Example 1 is shown. It was found that the thickness depending on a process cycle increase was linearly increased, and a self-limited reaction which is the characteristic of ALD was confirmed therefrom. In addition, in a graph of the thickness depending on a deposition cycle, the deposition speed which may be confirmed by a slope was 1.0 Å/cycle in Example 3, which was significantly improved as compared with 0.65 Å/cycle of Comparative Example 1.

In FIG. 8, the XRD patterns of Example 3 and Comparative Example 1 are shown. As for the specific deposition conditions, the temperature of the silicon substrate was 200° C., the precursor injection was for 0.5 seconds, the step of using plasma was performed with 400 sccm of nitrous oxide (N₂O) and a power of 400 W for 3 seconds, and the purging step was performed with 600 sccm of argon for 3 seconds, respectively. The thickness of each thin film was formed to be about 350 Å by adjusting the process cycle.

The deposited indium-containing oxide thin film was confirmed to have a cubic structure, and the results of each of the compositions and the thin film density through XPS and XRR analyses of the indium oxide thin film are shown in Table 2. As shown in Table 2, it was found that a pure indium oxide thin film having no impurities of carbon or nitrogen was formed, and the density of the thin film was 7.3 g/m³, which was confirmed to be similar to 7.2 g/m³ of the density in a bulk state.

TABLE 2

| | Composition ratio | | | | |
|---|---|---|---|---|---|
| | (%) by XPS | | | | Density of thin |
| | In3d | O1s | C1s | N | film (g/cm³) |
| Comparative Example 1 | 41.4 | 58.6 | 0.0 | 0.0 | 7.3 |
| Example 3 | 41.2 | 58.8 | 0.0 | 0.0 | 7.3 |

Thus, it was found that the metal compound according to an exemplary embodiment of the present invention was a compound in a liquid state and had surprisingly improved thermal stability, high volatility, and high vapor pressure. In addition, when the thin film was produced with the composition for depositing a thin film including the metal compound, a deposition thickness per one cycle which was higher by about 40% or more as compared with [(3-dimethylamino)propyl]dimethylindium (DADI) was shown, and thus, it was found that a much improved deposition speed was shown when the example of the present invention was used, and a thin film showing high reliability of uniform components was formed.

When the composition for depositing a thin film of the present invention is used, a thin film having a uniform thickness for a three-dimensional device may be provided, a thin film showing an appropriate composition ratio of a metal and oxygen may be produced, a time factor of a process may be decreased, and thus, the thin film may be produced very economically.

Hereinabove, although the present invention has been described by specific matters, the examples, and the comparative examples, they have been provided only for assisting in the entire understanding of the present invention. Therefore, the present invention is not limited to the above examples. Various modifications and changes may be made by those skilled in the art to which the present invention pertains from this description.

Therefore, the spirit of the present invention should not be limited to the above-described exemplary embodiments, and the following claims as well as all modifications equal or equivalent to the claims are intended to fall within the scope and spirit of the invention.

1. A composition for depositing a thin film comprising a metal compound, the metal compound being represented by the following Chemical Formula 1: 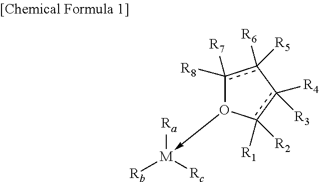
wherein;
M is In or Ga; [symbol]
is a single bond or a double bond;
Rₐ to R_{c} are each C1-C7 alkyl;
R₁ to R₈ are independently of one another hydrogen or C1-C7 alkyl; and
when [symbol] is a double bond, R₁, R₃, R₅, and R₇ do not exist.

2. The composition of claim 1, wherein:
Rₐ to R_{c} are each C1-C4 alkyl; and
R₁ to R₈ are independently of one another hydrogen or C1-C4 alkyl.

3. The composition of claim 1, wherein the metal compound is represented by the following Chemical Formula 2: 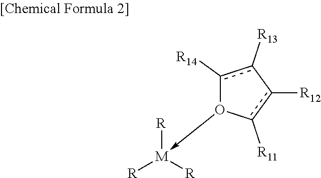
wherein:
M is In or Ga; [symbol]
is a single bond or a double bond;
R is C1-C7 alkyl; and
R₁₁ to R₁₄ are independently of one another hydrogen or C1-C7 alkyl.

4. The composition of claim 3, wherein, in Chemical Formula 2:
R is C1-C4 alkyl; and
R₁₁ to R₁₄ are independently of one another hydrogen or C1-C4 alkyl.

5. The composition of claim 1, wherein the metal compound is represented by the following Chemical Formula 3: 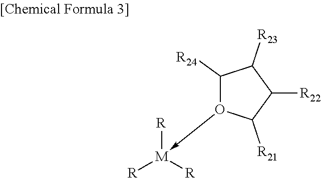
wherein:
M is In or Ga;
R is C1-C3 alkyl; and
R₂₁ to R₂₄ are independently of one another hydrogen or C1-C4 alkyl.

6. A method for producing a metal compound that is represented by the following Chemical Formula 1, the method comprising:
reacting compounds represented by the following Chemical Formulae 11 to 15 to produce the compound of Chemical Formula 1: 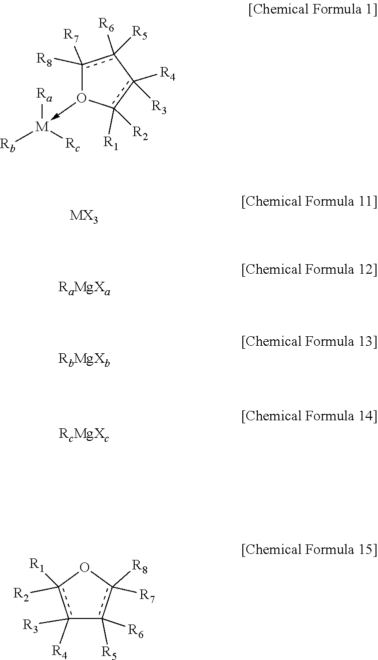
wherein:
M is In or Ga; [symbol]
is a single bond or a double bond;
Rₐ to R_{c} are each C1-C7 alkyl;
R₁ to R₈ are independently of one another hydrogen or C1-C7 alkyl;
X, Xₐ, X_{b}, and X_{c} are each a halogen; and
when [symbol] is a double bond, R₁, R₃, R₅, and R₇ do not exist.

7. The method of claim 6, further comprising:
adding a polar solvent to the produced compound of Chemical Formula 1.

8. The method of claim 7, wherein the polar solvent is added at from 2 to 5 equivalents with respect to the compound of Chemical Formula 1.

9. A method for producing a metal-containing thin film using (i) a metal compound that is represented by the following Chemical Formula 1 or (ii) a composition for depositing a thin film including the metal compound that is represented by the following Chemical Formula 1: 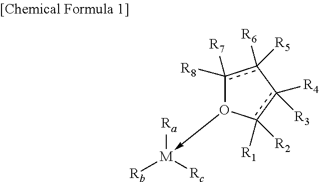
wherein;
M is In or Ga; [symbol]
is a single bond or a double bond;
Rₐ to R_{c} are each C1-C7 alkyl;
R₁ to R₈ are independently of one another hydrogen or C1-C7 alkyl; and
when [symbol] is a double bond, R₁, R₃, R₅, and R₇ do not exist.

10. The method of claim 9, further comprising:
heating a substrate mounted in a chamber;
injecting the (i) metal compound or (ii) the composition for depositing the thin film including the metal compound into the chamber and adsorbing (i) the metal compound or (ii) the composition for depositing the thin film including the metal compound to the substrate; and
injecting a reaction gas into the substrate to which the (i) metal compound or (ii) the composition for depositing the thin film including the metal compound is adsorbed to produce the metal-containing thin film.

11. The method of claim 10, wherein the substrate is heated to a temperature of from 100 to 450° C.

12. A metal-containing thin film produced using (i) a metal compound that is represented by the following Chemical Formula 1 or (ii) a composition for depositing a thin film including the metal compound that is represented by the following Chemical Formula 1: 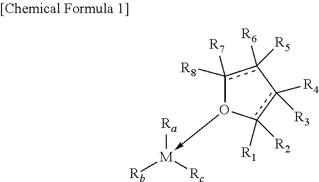
wherein:
M is In or Ga; [symbol]
is a single bond or a double bond;
Rₐ to R_{c} are each C1-C7 alkyl;
R₁ to R₈ are independently of one another hydrogen or C1-C7 alkyl; and
when [symbol] is a double bond, R₁, R₃, R₅, and R₇ do not exist.

13. The metal-containing thin film of claim 12, wherein the metal-containing thin film has a metal content of from 20 to 60 wt %, based on the total weight of the metal-containing thin film.
